(19) United States
(12) Patent Application Publication
(10) Pub. No.: US 2026/0040653 A1
(43) Pub. Date: Feb. 5, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Kohei OASA, Setagaya Tokyo (JP); Kentaro ICHINOSEKI, Higashimurayama Tokyo (JP); Yoko IWAKAJI, Meguro Tokyo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/022,792

(22) Filed: Jan. 15, 2025

(30) Foreign Application Priority Data
Aug. 5, 2024 (JP) 2024-128912

(51) Int. Cl. H10D 64/27; H10D 30/66; H10D 62/10; H10D 64/00

(52) U.S. Cl. CPC H10D 64/519; H10D 30/668; H10D 62/127; H10D 64/117

(57) ABSTRACT

A semiconductor device includes a first electrode, a substrate that has a first semiconductor region, a second semiconductor region and a third semiconductor region and a second electrode provided on the substrate. The semiconductor device has a conductor, an insulator, a gate electrode provided around the conductor and a gate insulating film. The gate insulating film has a plurality of curves. The plurality of curves includes a curve that has a first radius of curvature R1 and a curve that has a second radius of curvature R2 smaller than the first radius of curvature R1.

### CROSS-REFERENCE TO RELATED APPLICATIONS

This application is based upon and claims the benefit of priority from Japanese Patent Application No. 2024-128912 filed on Aug. 5, 2024, and the entire contents of which are incorporated herein by reference.

### FIELD

Embodiments described herein relate generally to a semiconductor device.

### BACKGROUND

Semiconductor devices with dot-shaped field plates, enabling improvement in breakdown voltage or reduction in on-resistance, are known.

### BRIEF DESCRIPTION OF THE DRAWINGS

FIG. 1 is a schematic plan view illustrating a semiconductor device according to a first embodiment;

FIG. 2 is a cross-sectional view taken along line A1-A2 illustrated in FIG. 1;

FIG. 3 is a cross-sectional view taken along line B1-B2 illustrated in FIG. 2;

FIG. 4 is a cross-sectional view focusing on the periphery of one conductor;

FIG. 5 is an enlarged cross-sectional view of an intersection of gate electrodes in a lattice shape;

FIG. 6A is a cross-sectional view illustrating the semiconductor device according to the first embodiment;

FIG. 6B is a cross-sectional view illustrating the semiconductor device according to the first embodiment;

FIG. 7 is a diagram illustrating a relationship between a gate voltage and a drain current;

FIG. 8 is a cross-sectional view illustrating a semiconductor device according to a second embodiment;

FIG. 9 is a cross-sectional view illustrating a semiconductor device according to a third embodiment;

FIG. 10 is a cross-sectional view illustrating a semiconductor device according to a fourth embodiment;

FIG. 11 is a cross-sectional view illustrating a semiconductor device according to a fifth embodiment;

FIG. 12 is a cross-sectional view illustrating a semiconductor device according to a sixth embodiment; and

FIG. 13 is a schematic plan view illustrating a semiconductor device according to a seventh embodiment.

### DETAILED DESCRIPTION

Hereinafter, each of embodiments of the present invention will be described with reference to the drawings.

Note that, the drawings are schematic or conceptual. The relationship between the thickness and the width of each portion, the ratio of the sizes between the portions, and the like are not necessarily the same as actual ones.

In addition, even in the case of representing the same portion, dimensions and ratios may be represented differently from each other depending on the drawings.

Note that, in the present specification and each drawing, the same elements as those described above with respect to the previously described drawings are denoted by the same reference numerals, and detailed description thereof will not be repeated.

A direction from a first electrode 11 to a second electrode 12 is defined as a Z direction (first direction).

A direction perpendicular to the Z direction is defined as an X direction (second direction), and a direction intersecting the X direction and the Z direction is defined as a Y direction (third direction). A semiconductor device 100 illustrated in FIG. 2 is illustrated in a cross-sectional view on the XZ plane.

Note that, the X direction, the Y direction, and the Z direction are illustrated in a perpendicular relationship in the present embodiment, but are not limited to the perpendicular relationship, and may be any relationship as long as they intersect each other.

For the sake of explanation, the positive direction in the Z direction is referred to as “upper”. The negative direction in the Z direction is referred to as “lower”. However, the “upper” and “lower” directions are not limited to the gravity direction or the direction at the time of mounting the semiconductor device.

In the XY plane, a direction positioned midway between the positive direction of the X direction and the positive direction of the Y direction is referred to as a fourth direction. For example, in a case where the X direction and the Y direction are perpendicular to each other, the fourth direction is a direction intersecting the positive direction of the X direction at an angle of 45 degrees and intersecting the positive direction of the Y direction at an angle of 45 degrees. In the XY plane, a direction positioned midway between the positive direction of the X direction and the negative direction of the Y direction is referred to as a fifth direction. For example, in a case where the X direction and the Y direction are perpendicular to each other, the fifth direction is a direction intersecting the positive direction of the X direction at an angle of 45 degrees and intersecting the negative direction of the Y direction at an angle of 45 degrees (the positive direction of the Y direction at an angle of 135 degrees). The fourth direction and the fifth direction are not limited to a relationship of being perpendicular to each other, and may be in a relationship of intersecting with each other.

In addition, in the following description, notations n⁺, n, and n⁻ and p⁺, p, and p⁻ represent relative high-low levels of the concentration of impurities in each conductivity type. That is, n⁺ indicates that the n-type impurity concentration is relatively higher than n, and n⁻ indicates that the n-type impurity concentration is relatively lower than n. In addition, p⁺ indicates that the p-type impurity concentration is relatively higher than p, and p⁻ indicates that the p-type impurity concentration is relatively lower than p. Note that n⁺-type and n⁻-type may be simply referred to as n-type, and p⁺-type and p⁻-type may be simply referred to as p-type.

### First Embodiment

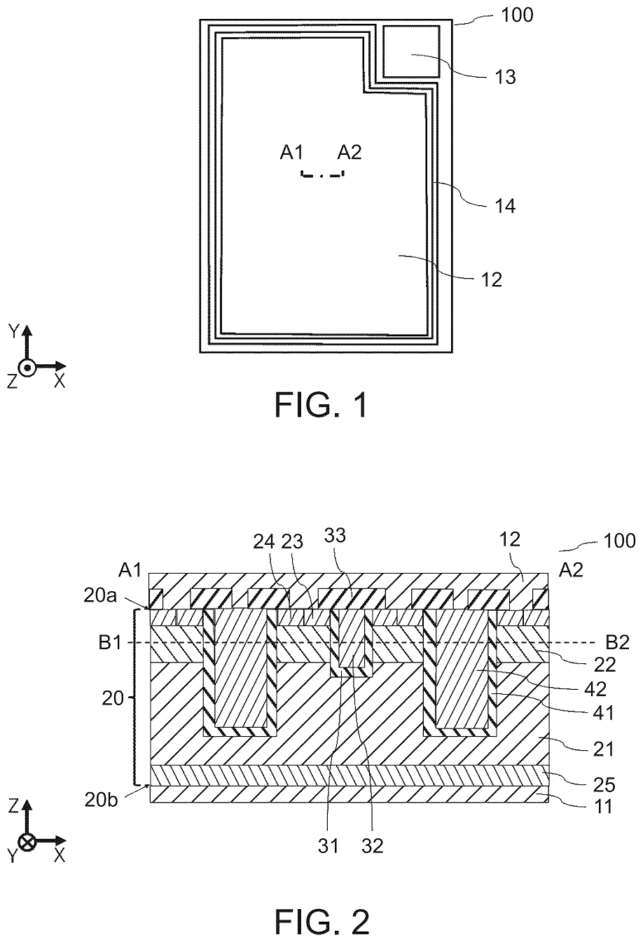

FIG. 1 is a schematic plan view illustrating a semiconductor device 100 according to the present embodiment. In FIG. 1, a first electrode 11 is not illustrated, and a second electrode 12, a gate pad 13, and a gate wiring 14 are illustrated. The gate wiring 14 and the gate pad 13 are electrically connected by wiring, which is not illustrated in FIG. 1. The second electrode 12 includes, for example, a source electrode of a metal oxide semiconductor field effect transistor (MOSFET). The first electrode 11 (not illustrated) includes, for example, a drain electrode of the MOSFET. The second electrode 12 is electrically insulated from the gate wiring 14 and the gate pad 13.

FIG. 2 is a cross-sectional view of the semiconductor device 100 taken along line A1-A2 illustrated in FIG. 1 in the XZ plane. However, line A1-A2 in FIG. 1 is an illustration for description, and may be different from an actual dimension. The semiconductor device 100 includes the first electrode 11, the second electrode 12, a substrate 20, a gate insulating film 31, a gate electrode 32, an insulating layer 33, an insulator 41, and a conductor 42. The substrate 20 is provided on the first electrode 11, and the second electrode 12 is provided on the substrate 20.

The substrate 20 includes a first semiconductor region 21 with a first conductivity type provided on the first electrode 11, a second semiconductor region 22 with a second conductivity type provided on the first semiconductor region 21, and a third semiconductor region 23 with the first conductivity type provided on the second semiconductor region 22. The third semiconductor region 23 is electrically connected to the second electrode 12. The first semiconductor region 21 is, for example, an n⁻-type drift region. The second semiconductor region 22 is, for example, a p-type base region. The third semiconductor region 23 is, for example, an n⁺-type source region.

FIG. 2 illustrates an example in which the substrate 20 further includes a fourth semiconductor region 24 and a fifth semiconductor region 25. The fourth semiconductor region 24 with the second conductivity type is selectively formed on the second semiconductor region 22. The fourth semiconductor region 24 is, for example, a p⁺-type contact region. In addition, the first semiconductor region 21 is electrically connected to the first electrode 11 via the fifth semiconductor region 25 with the first conductivity type. The fifth semiconductor region 25 is, for example, an n⁺-type drain region.

The gate electrode 32 extends from an upper surface 20a of the substrate 20 into the substrate 20, and the gate insulating film 31 covers the gate electrode 32. The gate electrode 32 is opposite to the second semiconductor region 22 and the third semiconductor region 23 with the gate insulating film 31 interposed therebetween. In addition, the insulating layer 33 is interposed between the gate electrode 32 and the second electrode 12, and the second electrode 12 and the gate electrode 32 are electrically insulated. Although not illustrated in FIG. 2, the gate electrode 32 is electrically connected to the gate wiring 14 and the gate pad 13 illustrated in FIG. 1.

The conductor 42 extends from the upper surface 20a of the substrate 20 into the substrate 20. The conductor 42 is opposite to the first semiconductor region 21 with the insulator 41 interposed therebetween. The conductor 42 is, for example, a field plate electrically connected to the second electrode 12, and reduces electric field concentration in the vicinity of the interface between the first semiconductor region 21 and the second semiconductor region 22 to improve the breakdown voltage of the semiconductor device 100 when the semiconductor device 100 is off. The conductor 42 may include at least a part thereof electrically connected to the gate electrode 32. The insulator 41 that covers the conductor 42 and the gate insulating film 31 that covers the gate electrode 32 are opposite to each other with the second semiconductor region 22 of the substrate 20 interposed therebetween.

The second electrode 12 is provided on the upper surface 20a of the substrate 20 so as to be electrically connected to the third semiconductor region 23. The second electrode 12 is further electrically connected to the fourth semiconductor region 24 and the conductor 42. The insulating layer 33 is provided between the second electrode 12 and the gate electrode 32. The insulating layer 33 may also be provided on at least a part of the conductor 42. The gate electrode 32 is provided between the first semiconductor region 21 and the second electrode 12. The conductor 42 is provided between the first semiconductor region 21 and the second electrode 12.

Next, an example of a material of each component will be described.

The substrate 20 contains, for example, Si. The material contained in the substrate 20 can be selected from semiconductor materials such as Si, Ge, GaAs, SiC, GaN, SiN, and AlN.

The semiconductor regions with the first conductivity type are formed by, for example, implanting an element such as P, As, N, or Sb into the substrate 20 and thermally diffusing the element. The semiconductor regions with the second conductivity type are formed by, for example, implanting an element such as B, Ga, Al, or Tl into the substrate 20 and thermally diffusing the element.

The gate insulating film 31 includes, for example, an oxide film containing silicon oxide. The gate electrode 32 includes, for example, conductive polysilicon containing impurities. The gate electrode 32 may include a metal containing W. The insulator 41 includes, for example, an oxide film containing silicon oxide. The conductor 42 includes, for example, conductive polysilicon containing impurities.

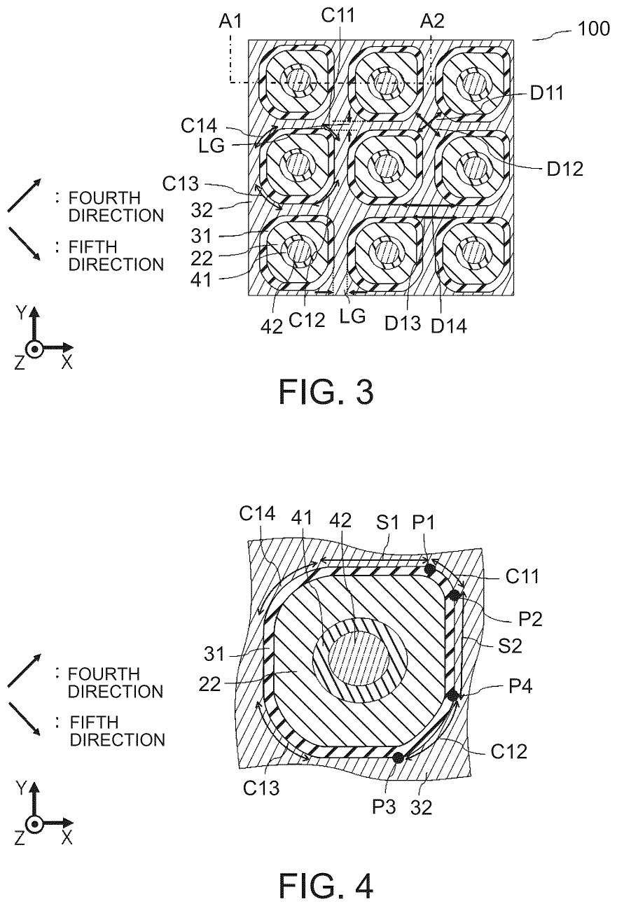

Subsequently, a planar structure of the semiconductor device 100 according to the present embodiment will be described with reference to FIG. 3. FIG. 3 is a cross-sectional view taken along line B1-B2 on the XY plane illustrated in FIG. 2. B1-B2 line passes through the second semiconductor region 22, the conductor 42, the insulator 41, the gate insulating film 31, and the gate electrode 32. The cross-sectional view illustrated in FIG. 2 is, for example, a cross-sectional view taken along line A1-A2 illustrated in FIG. 3.

As illustrated in FIG. 3, the gate electrodes 32 are provided in a lattice shape around a plurality of the conductors 42 provided in a dot shape in the X direction and the Y direction. Here, the lattice shape is a shape having a first portion extending in the X direction and a second portion extending in a direction intersecting the X direction (for example, the Y direction), and having a portion where the first portion and the second portion intersect with each other (hereinafter referred to as an intersection). In addition, in the case where the first portion and the second portion intersect with each other, the first portion and the second portion do not necessarily extend in both directions with respect to the intersection, and the intersection may be, for example, a T-shape or a Y-shape.

FIG. 3 illustrates an example in which the gate electrodes 32 are provided in a square lattice shape along the X direction and the Y direction. Note that the gate electrodes 32 are not limited to being provided in a square lattice shape, and may be provided in a rectangular or parallelogram lattice shape, or a honeycomb mesh lattice shape. The rectangular lattice (including a square lattice) is defined as a rectangular lattice, and the parallelogram lattice (including a rectangular lattice) is defined as a parallelogram lattice. In a case where the gate electrodes 32 are provided in the rectangular lattice shape, the X direction and the Y direction are perpendicular to each other. The X direction and the Y direction are not necessarily perpendicular to each other, and the gate electrodes 32 may be provided in the parallelogram lattice shape along the X direction and the Y direction.

The cross-sectional shape of the conductor 42 in the XY plane is desirably, for example, a circular shape in order to reduce local electric field concentration around the conductor 42, but is not limited to the circular shape.

The second semiconductor region 22 is provided around the insulator 41. The second semiconductor region 22 is opposite to the gate electrode 32 with the gate insulating film 31 interposed therebetween. The gate insulating film 31 is desirably provided with a uniform thickness around the second semiconductor region 22. In a case where the thickness of the gate insulating film 31 is non-uniform, the electric field may be concentrated on a thin portion of the gate insulating film 31. Hereinafter, the thickness of the gate insulating film 31 refers to a distance between the substrate 20 and the gate electrode 32, which are opposite to each other with the gate insulating film 31 interposed therebetween.

Except for the vicinity of the intersection of the gate electrodes 32, a width in the Y direction of a portion of the gate electrode 32 extending in the X direction and a width in the X direction of a portion of the gate electrode 32 extending in the Y direction each have, for example, a length LG. A structure in which the widths of the gate electrodes 32 in the X direction and the Y direction are formed to be equal is favorable to miniaturization. This is because in a case where the widths of the gate electrodes 32 are non-uniform, further miniaturization can be achieved by reducing the width of the gate electrode 32 in the direction with a smaller width.

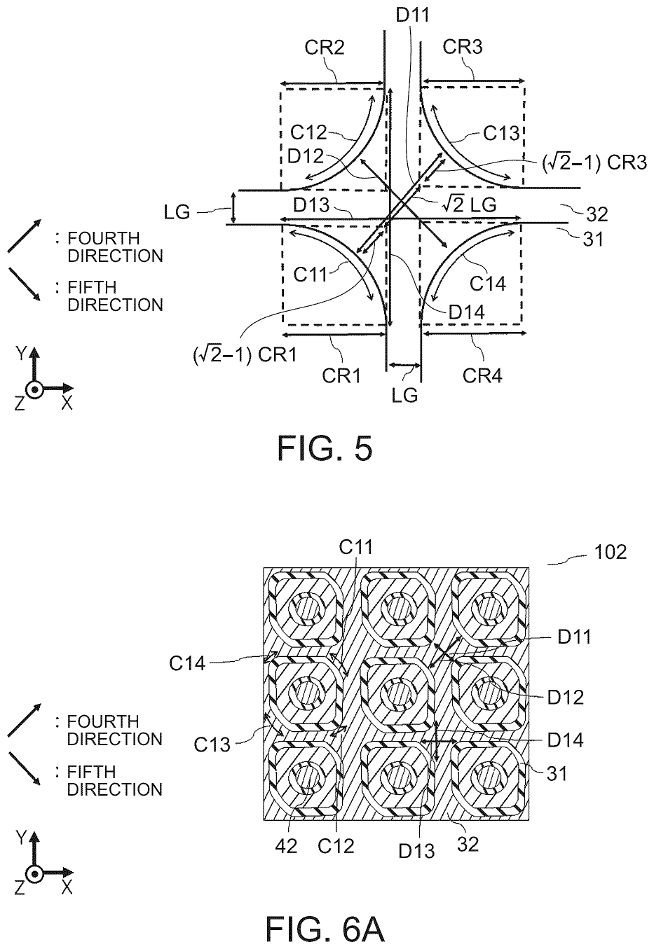

Curves C11 to C14 and lengths D11 to D14 illustrated in FIG. 3 will be described later with reference to FIGS. 4 and 5. Note that the definition of the curve will be described later with reference to FIG. 4.

Next, an example of a method for manufacturing the semiconductor device 100 will be described with reference to FIG. 2 again. While a structure on the upper surface 20a of the substrate 20 will be described in detail, a step of implanting impurities into the substrate 20 and thermally diffusing the impurities and a step of forming the first electrode 11 on a lower surface 20b will not be described.

First, the first semiconductor region 21 and the second semiconductor region 22 are excavated in the Z direction from the upper surface 20a of the substrate 20 to form an opening portion. A plurality of the opening portions is formed apart from each other in the X direction and the Y direction. The insulator 41 is formed by forming an oxide film on a surface of the opening portion by, for example, chemical vapor deposition (CVD). Next, the conductor 42 is formed by embedding conductive polysilicon by, for example, CVD.

On the other hand, the second semiconductor region 22 is removed in the Z direction from the upper surface 20a of the substrate 20 to form a recessed portion. The recessed portions are formed in a lattice shape to surround the conductor 42 provided in a dot shape in the XY plane. For example, a mask is provided on the upper surface 20a of the substrate 20 by, for example, photolithography, and the upper surface 20a of the substrate 20 is selectively removed by etching or the like to form the recessed portions.

The gate insulating film 31 is formed by forming an oxide film on a surface of the recessed portion by, for example, CVD or thermal oxidation. The gate electrode 32 is formed by embedding conductive polysilicon in contact with the gate insulating film 31 using, for example, CVD. The insulating layer 33 is formed to cover the gate electrode 32. The insulating layer 33 is provided on the upper surface of the substrate 20 by, for example, CVD. Thereafter, a resist pattern is formed on the insulating layer 33 by photolithography, and etching is then performed to form a pattern.

For example, the conductor 42 is formed, followed by the formation of the gate electrode 32. However, the order of providing the gate electrode 32 and the conductor 42 is not limited thereto. In a case where the conductor 42 is formed, followed by the formation of the gate electrode 32, the gate insulating film 31 may also be formed on the conductor 42. Therefore, a step of selectively removing the gate insulating film 31 at a portion positioned on the conductor 42 may be included.

Subsequently, the second electrode 12 is formed on the upper surface 20a of the substrate 20 to be connected to the conductor 42 and opposite to the gate electrode 32 with the insulating layer 33 interposed therebetween, for example, by sputtering.

In the above-described manufacturing steps, in the step of excavating the substrate 20 in the Z direction to form the lattice-shaped recessed portions, the amount of excavation of the substrate 20 at some of the intersections in the lattice can be adjusted. For example, the lattice shape of the recessed portions at the intersections can be controlled by appropriately selecting the shape of the mask provided by photolithography. Subsequently, in the step of forming the gate insulating film 31, for example, a shape of the interface between the gate insulating film 31 and the gate electrode 32 can be controlled by forming an oxide film with a uniform thickness on the surface of the recessed portion as described later with reference to FIGS. 4 and 5.

Next, a cross-sectional view along the XY plane will be further described with reference to FIG. 4. FIG. 4 illustrates a cross-sectional view focusing on the periphery of a certain conductor 42 in the planar structure illustrated in FIG. 3. First, the definitions of the curves C11, C12, C13, and C14 will be described.

The curve C11 is defined as a region between the points P1 and P2 with respect to the shape of the gate insulating film 31 in the XY plane as illustrated in FIG. 4. The points P1 and P2 are positioned in the positive direction of the X direction and the positive direction of the Y direction with respect to the conductor 42. The point P1 is, in the interface between the gate insulating film 31 and the gate electrode 32, an end point in the positive direction of the X direction of a region S1 positioned in the positive direction of the Y direction with respect to the conductor 42 and having the interface parallel to the X axis. In addition, the point P2 is, in the interface between the gate insulating film 31 and the gate electrode 32, an end point in the positive direction of the Y direction of a region S2 positioned in the positive direction of the X direction with respect to the conductor 42 and having the interface parallel to the Y axis. Note that the regions S1 and S2 are not necessarily long regions, and may be points. In a case where the regions S1 and S2 are points, the regions S1 and S2 themselves are regarded as end points.

The curve C11 is a corner portion of the gate insulating film 31 in the XY plane. Here, the corner portion includes a rounded shape. That is, the gate insulating film 31 has the corner portion in the XY plane. Although a radius of curvature of a curve will be described below, the radius of curvature may be read as a radius of curvature of a corner portion.

In the XY plane, the gate insulating film 31 is, for example, annularly provided between the second semiconductor region 22 and the gate electrode 32 as illustrated in FIG. 4. The curve C11 of the gate insulating film 31 is a region positioned between the points P1 and P2 out of portions in contact with the gate electrodes 32. In the following description, the fact that the shape of the gate insulating film 31 in the XY plane has a curve may be simply expressed as that the gate insulating film 31 has a curve. As illustrated in FIG. 11 later, the curve C11 may partially include a region whose tangent is in the direction along the X axis or the Y axis.

In the example illustrated in FIG. 4, the gate insulating film 31 has four curves per conductor 42, and the curves are referred to in order clockwise from the curve C11 as the curves C12, C13, and C14. Also in the positive direction of the X direction and the negative direction of the Y direction with respect to the conductor 42, the point P3 is defined similarly to the point P1, and the point P4 is defined similarly to the point P2. A region between the point P3 and the point P4 is referred to as the curve C12. The curves C13 and C14 are similarly defined.

Next, the derivation of a radius of curvature will be described. Hereinafter, a radius of curvature of the curve C11 means a radius of curvature derived based on the assumption that the curve C11 has a constant curvature. That is, the radius of a circular arc that passes through the points P1 and P2 and smoothly connects the regions S1 and S2 of the interface between the gate insulating film 31 and the gate electrode 32 at the points P1 and P2 is determined as the radius of curvature of the curve C11. A radius of curvature of a curve can be derived by, for example, determining points at both ends of the curve (the points P1 and P2 for the curve C11), overlapping a circular arc having a predetermined radius, and evaluating.

A method for deriving a radius of curvature different from the above-described method will be described with reference to FIG. 5. FIG. 5 is an enlarged cross-sectional view of an intersection of gate electrodes in a lattice shape. The hatching is omitted and is not illustrated. It is assumed that the lengths LG, which are the widths of the lattice-shaped gate electrodes 32, are uniform except in the vicinity of the intersection. A distance between the curves (curve C11 and curve C13) opposite to each other in the fourth direction positioned midway between the positive direction of the X direction and the positive direction of the Y direction is denoted by D11. A radius of curvature of the curve C11 is denoted by CR1, and a radius of curvature of the curve C13 is denoted by CR3.

As illustrated in FIG. 5, the length D11 is equal to √2LG+(√2−1) (CR1+CR3). That is, an arithmetic mean of CR1 and CR3 is (CR1+CR3)/2=(D11−√2LG)/(2(√2−1)). Hereinafter, the arithmetic mean is simply referred to as an average. In a case where the radius of curvature CR1 is equal to the radius of curvature CR3 (CR1=CR3), CR1=CR3=(D11−√2LG)/(2(√2−1)) is established.

That is, in a case where the length LG is known, the average of CR1 and CR3 can be obtained by measuring the length D11.

Furthermore, a length D12 is defined as a distance between the curves (curve C12 and curve C14) opposite to each other in the fifth direction perpendicular to the fourth direction. Similarly, for the length D12, the average radius of curvature of the curve C12 and the curve C14 can be derived by calculating (D12−√2LG)/(2(√2−1)).

Next, a length D13 and a length D14 will be described.

The length D13 is the maximum value of a distance in the X direction between curves (curves C11 and C14 or curves C12 and C13) opposite to each other with the gate electrode 32 interposed therebetween in the X direction. The length D14 is the maximum value of a distance in the Y direction between curves (curves C11 and C12 or curves C13 and C14) opposite to each other with the gate electrode 32 interposed therebetween in the Y direction.

Since the length D13 illustrated in FIG. 5 is a length obtained by combining the radius of curvature CR1 of the curve C11, a radius of curvature CR4 of the curve C14, and the length LG, the average radius of curvature of the curve C11 and the curve C14, namely (CR1+CR4)/2 can be derived from (D13−LG)/2. The length D13 is not limited to the case illustrated in FIG. 5, and may be defined between the curves C12 and C13, and the average radius of curvature of the curve C12 and the curve C13, namely (CR2+CR3)/2 can be derived.

Similarly, the average radius of curvature of the curve C11 and the curve C12, namely (CR1+CR2)/2 can be derived from (D14−LG)/2. The length D14 is not limited to the case illustrated in FIG. 5, and may be defined between the curves C13 and C14. The average radius of curvature of the curve C13 and the curve C14, namely (CR3+CR4)/2 can be derived.

As described above, assuming that the curve is along the circular arc, the average radius of curvature of any two curves (all six combinations) out of the four curves C11 to C14 can be derived from the length LG and a value of the length D11, D12, D13, or D14. The curve is not limited to being completely along the circular arc, the magnitude relationship between the radii of curvature can be evaluated from the magnitude relationship between the lengths D11, D12, D13, and D14. For example, in a case where the lengths of D11 and D12 are different from each other, it can be seen that at least two types of radii of curvature are included. That is, the radius of curvature can be evaluated by measuring the length D11, D12, D13, or D14 instead of directly measuring the radius of curvature.

A plurality of the curves include curves, each having a first radius of curvature R1 and a second radius of curvature R2 smaller than the first radius of curvature R1. In other words, in a case where a certain reference length LS is determined, a curve in which a radius of curvature is smaller than the reference length LS and a curve in which a radius of curvature is larger than the reference length LS are included. The reference length LS satisfies, for example, R1<LS<R2, and may be determined as LS=(R1+R2)/2.

In addition to the first radius of curvature R1 and the second radius of curvature R2 (R2<R1), the curve may have a third radius of curvature R3 smaller than the second radius of curvature (R3<R2), or may have a fourth radius of curvature R4 smaller than the third radius of curvature (R4<R3).

Hereinafter, a curve having a large radius of curvature means the curve having the first radius of curvature R1. A curve having a small radius of curvature means the curve having the second radius of curvature R2.

The curve having a large radius of curvature is desirably provided with respect to each of a plurality of the conductors 42 in a common direction. In addition, the curve having a small radius of curvature is desirably provided with respect to each of the conductors 42 in a common direction.

For example, in the examples illustrated in FIGS. 3 and 4, the curve C11 is a curve having a small radius of curvature, and the curves C12, C13, and C14 are curves, each having a large radius of curvature. As illustrated in FIG. 3, the curves, each having a large radius of curvature, are provided commonly in the negative direction of the fourth direction and the positive and negative directions of the fifth direction with respect to the individual conductors 42. On the other hand, the curves, each having a small radius of curvature, are provided commonly in the positive direction of the fourth direction with respect to the individual conductors 42. In the example of FIG. 3, the length D11 is smaller than the length D12, and the length D13 is smaller than the length D14.

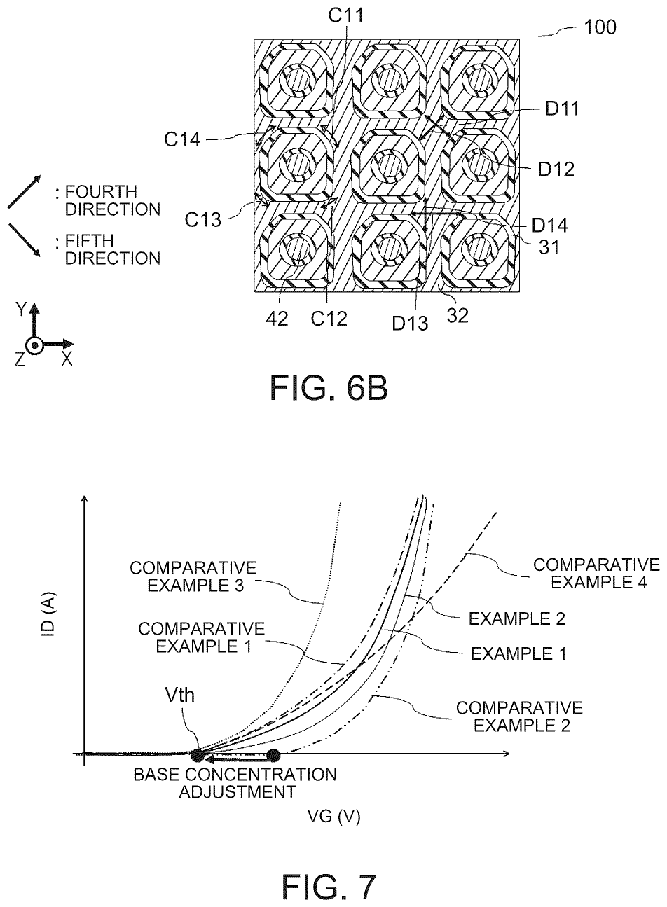

Next, examples of the magnitude relationship between the lengths D11 to D14 will be further described with reference to FIGS. 6A and 6B. FIG. 6A illustrates a structure in which D11 and D12 have a predetermined magnitude relationship, and FIG. 6B illustrates a structure in which D13 and D14 have a predetermined magnitude relationship.

FIG. 6A illustrates an example of D11>D12. The average radius of curvature of the curve C11 and the curve C13 is larger than the average radius of curvature of the curve C12 and the curve C14. At least one of the curve C11 or the curve C13 has the first radius of curvature R1, and at least one of the curve C12 or the curve C14 has the second radius of curvature R2.

The magnitude relationship between the length D13 and the length D14 may satisfy D13<D14 or D13>D14. In addition, D13=D14 may be satisfied.

On the other hand, FIG. 6B illustrates an example of D13>D14. The average radius of curvature of the curve C11 and the curve C14 is larger than the average radius of curvature of the curve C12 and the curve C13. At least one of the curve C11 or the curve C14 has the first radius of curvature R1, and at least one of the curve C12 or the curve C13 has the second radius of curvature R2.

The magnitude relationship between the length D11 and the length D12 may satisfy D11<D12 or D11>D12. In addition, D11=D12 may be satisfied.

In FIGS. 6A and 6B, the number of the curves having a large radius of curvature per conductor 42 is, for example, two. However, the present embodiment is not limited to the examples illustrated in FIGS. 6A and 6B, and the number of the curves having a large radius of curvature may be one or three out of the four curves.

An operation of the semiconductor device 100 will be described with reference to FIG. 2 again. In a state where a positive voltage is applied to the first electrode 11 with respect to the second electrode 12, a voltage equal to or higher than a threshold value is applied to the gate electrode 32. As a result, a channel (inversion layer) with the first conductivity type is formed in the second semiconductor region 22 with the second conductivity type, and the semiconductor device 100 is turned into the on state.

Electrons flow from the second electrode 12 to the first electrode 11 through the channel. Specifically, the electrons flow from the second electrode 12 to the first electrode 11 through the third semiconductor region 23, a channel generated in the second semiconductor region 22, the first semiconductor region 21, and the fifth semiconductor region 25.

Thereafter, in a case where the voltage applied to the gate electrode 32 is lower than the threshold value, the channel in the second semiconductor region 22 disappears, and the semiconductor device 100 is turned into the off state.

In a case where the semiconductor device 100 is switched to the off state, the positive voltage applied to the first electrode 11 with respect to the second electrode 12 increases. A depletion layer expands in a direction from the second semiconductor region 22 toward the first semiconductor region 21.

In addition, in a case where the depletion layer expands in the first semiconductor region 21, out of carriers (electrons and holes) generated by impact ionization or the like, electrons are mainly discharged from the first electrode 11 through the fifth semiconductor region 25, and holes are mainly discharged to the second electrode 12 through the fourth semiconductor region 24.

The relationship between the operation of the semiconductor device 100 according to the present embodiment and the shapes of the curves will be further described with reference to FIG. 3 again.

When a voltage is applied to the gate electrode 32, an electric field is induced in the second semiconductor region 22 via the gate insulating film 31. As the radius of curvature of the curve of the gate insulating film 31 gets smaller, the concentration of the electric field is promoted, and the electric field strength tends to increase. That is, as the radius of curvature of the curve of the gate insulating film 31 is smaller, the channel is more likely to be formed in the second semiconductor region 22, and the semiconductor device 100 is more likely to be locally turned on.

Hereinafter, the fact that a channel is formed in the second semiconductor region 22 in the vicinity of the curve of the gate insulating film 31 may simply be referred to as the channel being formed in the curve. In a case where the voltage applied to the gate electrode 32 is gradually increased, a channel is first t formed in a curve where electric field concentration is likely to occur in the second semiconductor region 22, and a channel is then formed in, for example, the region S1 or S2 in FIG. 4 positioned between the curves in the gate insulating film 31, resulting in the semiconductor device 100 being completely turned on.

In a case where a plurality of curves have different radii of curvature, and the voltage applied to the gate electrode 32 is increased, a channel is firstly formed in the curve having a small radius of curvature, followed by the formation of a channel in the curve having a large radius of curvature. This is because the concentration of the electric field is promoted as the radius of curvature is small.

As the radius of curvature of the curve of the gate insulating film 31 is smaller, a threshold voltage of the gate electrode 32 decreases. The threshold voltage of the gate electrode 32 is determined by the smallest radius of curvature out of the curves. This is because in a case where the radius of curvature of at least one curve is small, a channel is formed locally at the curve, resulting in the semiconductor device 100 being turned on.

The threshold voltage at which the channel is formed also varies depending on the concentration in the second semiconductor region 22. As the concentration of impurities contained in the second semiconductor region 22 increases, a channel is less likely to be formed and the threshold voltage increases.

It is generally known that when the voltage applied to the gate electrode 32 is gradually increased from around the threshold voltage, the slower the increase in current (in other words, the current increase rate is small), the wider the safety operation region (SOA). Here, the current increase rate (=ΔID/ΔVG) is defined as a magnitude of an increment (ΔID) in a drain current with respect to an increment (ΔVG) in a gate voltage. In a low-voltage region that is a relatively low gate voltage and close to the threshold voltage, it is desirable to reduce the current increase rate in order to increase the SOA. It is possible to suppress a rapid increase or decrease of the current flowing at the moment when the semiconductor device 100 is locally turned on (at the time of switching).

In addition, even in a case where a reduction in on-resistance is desired in the design of a power device, a constraint to maintain threshold voltage at a predetermined value may occur. This is because a threshold voltage suitable for a circuit to be used may be determined as a standard. For example, a predetermined Vth value such as 3 V or 5 V may be required depending on the intended application. Therefore, it is desirable to make the increase in the current increase rate more gradual at the gate voltage around the predetermined threshold voltage.

According to the semiconductor device 100 of the present embodiment, by setting the radii of curvature of the curves to be different from each other, it is possible to make the increase in the current increase rate more gradual in the low-voltage region with the predetermined threshold voltage maintained to suppress a rapid increase or decrease of the current at the time of switching, thereby improving the reliability of the semiconductor device. In addition, the on-resistance can be reduced as described below. In other words, in a case where the predetermined threshold value is determined as a designed value, the on-resistance can be reduced.

FIG. 7 illustrates a relationship between a gate voltage VG and a drain current ID in the present embodiment and comparative examples. Example 1 indicates that the number of the curves having a large radius of curvature formed is smaller than that in Example 2. Example 1 indicates an example in which the radius of curvature of one curve out of the four curves is increased, for example, in the present embodiment (for example, the shape illustrated in FIG. 4). Example 2 indicates an example in which the radius of curvature of three curves out of the four curves is increased, for example, in the present embodiment, which corresponds to FIG. 3, for example.

Comparative Example 1 corresponds to a case where all of the four curves are formed to have the same radius of curvature as the curve having the smallest radius of curvature out of the curves in Examples 1 and 2. Comparative Example 2 is a structure in which all of the four curves are formed to have the same radius of curvature as the curve having the largest radius of curvature out of the curves in Examples 1 and 2. That is, Comparative Examples 1 and 2 indicate examples in which the radii of curvature of all the curves are formed to be equal.

For each of the above-described examples, the ratio of the number of the curves having the first radius of curvature R1 and the second radius of curvature R2 (<R1) is summarized as follows:
(1) in Example 1, the number of the curves having the first radius of curvature R1: the number of the curves having the second radius of curvature R2=1:3;
(2) in Example 2, the number of the curves having the first radius of curvature R1: the number of the curves having the second radius of curvature R2=3:1;
(3) in Comparative Example 1, the number of the curves having the first radius of curvature R1: the number of the curves having the second radius of curvature R2=0:4; and
(4) in Comparative Example 2, the number of the curves having the first radius of curvature R1: the number of the curves having the second radius of curvature R2=4:0.

Comparative Example 3 is an example in which the concentration of impurities in a base region (corresponding to the second semiconductor region 22 of the present application) is decreased in order to adjust the threshold voltage to a predetermined value although having the same shape of curve as that of Comparative Example 2. Comparative Example 4 is an example in which curves, each having a radius of curvature further smaller than R2, are uniformly formed, and the concentration of impurities in a base region is increased in order to adjust the threshold voltage to a predetermined value.

First, Comparative Example 1 and Example 1 will be described in comparison. In Comparative Example 1 and Example 1, when a gate voltage VG is larger than Vth, a drain current ID begins to flow, and the semiconductor device 100 is then turned on. Here, Vth is a threshold voltage at which a channel is formed in a curve having the smallest radius of curvature out of a plurality of curves. The value of the threshold voltage Vth varies depending on the magnitude of a radius of curvature of the curve. As the slope of the curve in the vicinity of VG=Vth is steeper (the current increase rate is larger), the variation in current tends to be increased at the time of switching. In contrast, as the slope of the curve is gentler (the current increase rate is smaller), a rapid variation in current is suppressed at the time of switching, and the SOA is increased, which is desirable.

In addition, in a region where VG is sufficiently larger than Vth, it is desirable to allow a larger ID with a smaller VG, since this reduces the on-resistance. In a region where VG is sufficiently larger than Vth, it is desirable to make the slope of the curve in FIG. 7 steeper.

That is, it is desirable to reduce the on-resistance by making the slope of the curve in the vicinity of VG=Vth gentler and making the slope of the curve steeper in a region where VG is sufficiently larger than Vth.

There is no significant difference in the value of Vth between Comparative Example 1 and Example 1. This is because the value of Vth is determined by the curve having the smallest radius of curvature, but in Example 1, at least one curve is formed with the same radius of curvature as that of the curve in Comparative Example 1.

In Example 1, the slope of the curve is gentler in the vicinity of VG=Vth than that in Comparative Example 1. Therefore, the SOA can be increased. This is because the number of the curves having a small radius of curvature is limited to some curves in Example 1. A region where a channel is formed is limited in the vicinity of VG=Vth, and a rapid increase in current is suppressed.

In addition, in Example 1, a region where VG is sufficiently larger than Vth has an equivalent level of on-resistance to that of Comparative Example 1. This is because there is no difference in the concentration of impurities in the base region for determining the on-resistance, and there is also no large difference in the total area (also referred to as a gate length) in which the gate electrode and the base region are opposite to each other.

Next, Example 2 will be described. Example 2 is an example in which a larger number of the curves having a large radius of curvature are formed than that in Example 1. In Example 2, the slope of the curve is gentler (the current increase rate is smaller) in the vicinity of VG=Vth than that in Example 1. In addition, a region where the gate voltage VG is sufficiently large, Example 1 and Example 2 have equivalent on-resistance values, for example.

In Example 2, the reason why the slope of the curve is gentle in the vicinity of VG=Vth is that the number or ratio of the curves having a small radius of curvature decreases. In Example 2, one curve out of the four curves is formed to have a small radius of curvature alone, and the one curve out of the four curves in the vicinity of VG=Vth is turned on. Since at least one curve having a small radius of curvature is provided, an increase in the threshold voltage can be suppressed.

That is, in Example 2, the SOA can be further increased to improve the reliability of the semiconductor device as compared with Example 1.

Next, Comparative Example 2 will be described. Comparative Example 2 has a larger Vth than those in Comparative Example 1 and Examples 1 and 2. This is because Comparative Example 2 includes the curves, all of which have larger radius of curvature than the smallest radius of curvature included in Comparative Example 1, and Examples 1 and 2. In Comparative Example 2, the required gate voltage value for the curves to be turned on increases.

The value of the threshold voltage may need to be adjusted to a predetermined value. Accordingly, Comparative Example 3 is an example in which the base concentration in Comparative Example 2 is adjusted in order to approach the value of the threshold voltage Vth in Comparative Example 1. Comparative Example 3 indicates an example in which a channel is easily formed by reducing the base concentration, and the threshold voltage is thus reduced as compared with Comparative Example 2, thereby approaching Vth.

It is possible to bring the threshold voltage close to a predetermined value (Vth) by adjusting the base concentration. On the other hand, in Comparative Example 3, the curves have a large radius of curvature, and the difference between the gate voltage at which the current begins to flow in the curve and the gate voltage at which the current begins to flow in the planar region between the curves (S1 or S2 in FIG. 4) is small. Therefore, there is a probability that the current begins to flow rapidly at the gate voltage close to the threshold voltage. That is, the current increase rate increases in the vicinity of VG=Vth. In Comparative Example 3, the current rapidly varies at the time of switching, and the SOA decreases, which is not desirable.

Finally, Comparative Example 4 illustrated in FIG. 7 is an example in which all of the curves have a third radius of curvature R3 (<R2) smaller than the second radius of curvature R2. There is a large difference between the gate voltage at which the current begins to flow in the curve and the gate voltage at which the current begins to flow in the planar region (S1 or S2 in FIG. 4) between the curves. In order to adjust the threshold voltage decreasing in the curve to a predetermined threshold voltage value, the threshold voltage is maintained at Vth by increasing the base concentration. By increasing the base concentration, the gate voltage at which the current begins to flow in the planar region (S1 or S2 in FIG. 4) between the curves increases. Therefore, the on-resistance in the region where the gate voltage is sufficiently large may increase. That is, in Comparative Example 4, the on-resistance may increase when the threshold voltage is maintained at a predetermined value.

That is, according to Examples 1 and 2 included in the semiconductor device 100 of the present embodiment, since the curves having a small radius of curvature and the curves having a large radius of curvature are provided to reduce the current increase rate in the low-voltage region where the gate voltage is close to Vth, it is possible to suppress a rapid increase in current according to the increase in the gate voltage, while maintaining a low on-resistance in the high-voltage region of the gate voltage. It is possible to expand the SOA by suppressing the rapid current variation at the time of switching while suppressing an increase in the on-resistance, that is, it is possible to improve reliability.

In addition, in the example of FIG. 6A, with respect to the conductors 42, the curves having a large radius of curvature are positioned in the positive and negative directions of the fourth direction, and the curves having a small radius of curvature are positioned in the positive and negative directions of the fifth direction. That is, two curves having a large radius of curvature and two curves having a small radius of curvature are positioned at an intersection of the gate electrodes 32. Therefore, it is possible to suppress the concentration of either one of the curves having a large radius of curvature or the curves having a small radius of curvature at one intersection.

In general, the curves having a large radius of curvature (a small radius of curvature) are provided in a common direction for each of the conductors 42, so that at least one curve having a large radius of curvature and at least one curve having a small radius of curvature are positioned at one intersection of the gate electrodes 32. Therefore, it is possible to suppress the concentration of the current at one intersection at the time of switching and to further disperse the current density at the time of switching. It is possible to further improve the reliability by dispersing heat generating portions.

### Second Embodiment

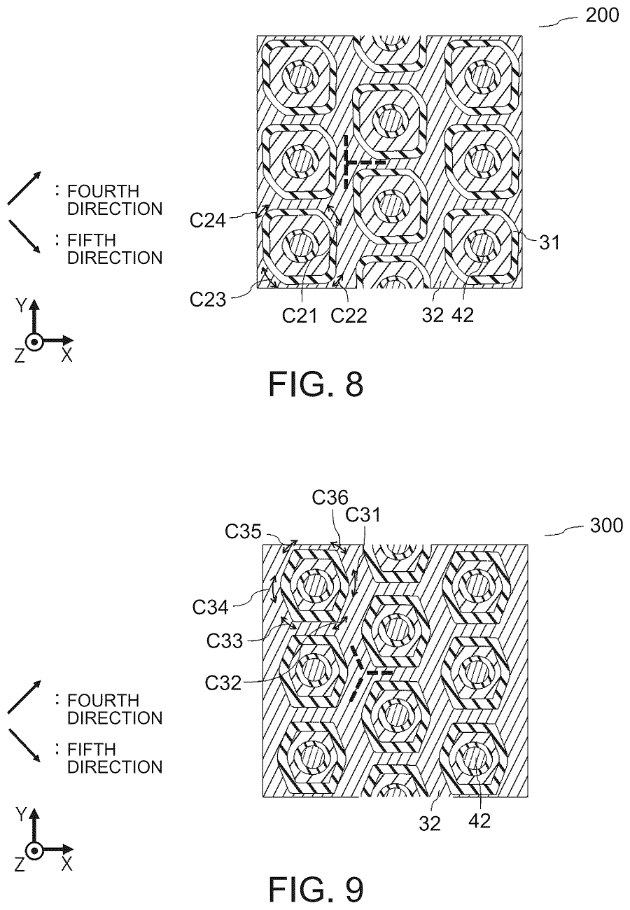

FIG. 8 is a cross-sectional view of a semiconductor device 200 according to a second embodiment. The description of common parts with the first embodiment will not be repeated, and different parts will be described.

In the example illustrated in FIG. 8, the gate electrodes 32 are arranged in a lattice shape, and the shape of an intersection of the lattice is a T-shape or a Y-shape. FIG. 8 illustrates an example of a T-shaped intersection with a dotted line. In other words, the conductors 42 are provided at positions corresponding to vertices of the triangular lattice in the XY plane.

The gate insulating film 31 has four curves per conductor 42. A curve C21 is a curve positioned in the positive direction of the X direction and the positive direction of the Y direction. The respective curves are referred to in order clockwise from the curve C21 as curves C22, C23, and C24.

A plurality of the curves includes a first radius of curvature R1 and a second radius of curvature R2 smaller than the first radius of curvature R1. FIG. 8 illustrates an example in which the radius of curvature of the curve C21 and the curve C23 out of the four curves is formed to be larger than the radius of curvature of the other two curves.

According to a semiconductor device 200 of the present embodiment, the concentration of current can be suppressed by dispersing the positions of the curves in the XY plane. In the semiconductor device 200 according to the present embodiment, two curves are positioned per intersection of the lattice-shaped gate electrodes 32. Therefore, it is possible to reduce the concentration of current by dispersing the arrangement of the curve through which the current flows at the time of switching.

In the semiconductor device 100 according to the present embodiment, four curves are positioned per intersection of the lattice-shaped gate electrodes 32. On the other hand, since the number of the curves per intersection of the gate electrodes 32 is small in the semiconductor device 200 according to the present embodiment, the density of current flowing through the intersection of the gate electrodes 32 in the vicinity of VG=Vth can be reduced at the time of switching, so that the reliability can be further improved.

Furthermore, with respect to the conductors 42 provided, the curves having a small radius of curvature are positioned in a common direction (for example, the positive and negative directions of the fifth direction in FIG. 8). Thus, it is possible to reduce the concentration of the curves having a small radius of curvature at one intersection, and to disperse the portions where the current flows at the time of switching. For example, in the example of the T-shaped intersection illustrated in FIG. 8, the curves having a small radius of curvature are distributed one by one per intersection. By dispersing the current flowing at each of the T-shaped intersections at the time of switching, it is possible to disperse the heat generating portions and improve the reliability of the semiconductor device.

### Third Embodiment

FIG. 9 is a cross-sectional view of a semiconductor device 300 according to a third embodiment. Some redundant descriptions of the components common to the semiconductor device 200 according to the second embodiment will not be repeated.

In the semiconductor device 300 according to the present embodiment, the number of the curves per conductor 42 is not limited to four curves. FIG. 9 illustrates a case where the gate insulating film 31 has a hexagonal shape and has six curves. The gate electrodes 32 are arranged in a lattice shape of a honeycomb mesh shape, and the shape of an intersection of the lattice is, for example, a Y-shape as illustrated by a dotted line in FIG. 9. Besides this, eight curves or three curves may be provided per conductor 42.

A curve positioned in the positive direction of the X direction as viewed from the conductor 42 is referred to as a curve C31. The respective curves are referred to in order clockwise from the curve C31 as curves C32, C33, C34, C35, and C36. In the example illustrated in FIG. 9, the curves C31 and C34 have larger radius of curvature than those of the curves C32, C33, C35, and C36.

In addition, the example in which the number of the curves having a large radius of curvature is two out of the six curves has been described, but the number of the curves having a large radius of curvature may be one or three, or may be four or five out of the six curves. For example, as illustrated in FIG. 9, a structure in which the curves having a large radius of curvature (or a small radius of curvature) are provided on a diagonal line of the hexagonal shape of the gate insulating film 31 is desirable because the curves having a large radius of curvature (or a small radius of curvature) are dispersed at a plurality of the intersections of the lattice-shaped gate electrodes 32.

In general, when the curves having a large radius of curvature (or a small radius of curvature) are provided on the diagonal lines of the hexagonal shape of the gate insulating film 31, the curves having a large radius of curvature (a small radius of curvature) are positioned while being dispersed at the intersections of the lattice-shaped gate electrodes 32, which is desirable.

According to a semiconductor device 300 according to the present embodiment, the number of the curves per conductor 42 may be six or may be further increased, and a ratio of the presence of the curves having a small radius of curvature and the curves having a large radius of curvature can be more finely adjusted than the semiconductor device 200 according to the second embodiment. In other words, it is possible to more finely adjust a ratio of the curves having a large radius of curvature to the total number of the curves (hereinafter, referred to as a first ratio RT1).

The first ratio RT1 is defined as follows. In the case where the reference length LS is determined, the number of curves having a radius of curvature longer than the reference length LS out of a plurality of curves is denoted by NL, and the number of curves having a radius of curvature shorter than the reference length LS is denoted by NS. The first ratio RT1 can be defined as NL/(NL+NS). As a method of determining the reference length LS, provided that the curves have at least two types of radii of curvature, that is, the first radius of curvature R1 and the second radius of curvature R2 smaller than the first radius of curvature R1, the reference length LS can be determined, for example, as LS=(R1+R2)/2 within a range of R2<LS<R1.

For the comparison, in the semiconductor device 200 according to the second embodiment, it is possible to increase the radius of curvature in one, two, or three curves out of the four curves. That is, the first ratio RT1 can be selected from ¼, 2/4, and ¾. In addition, the first ratio RT1 has a value within a range of ¼ or more and ¾ or less by combining and arranging structures in which the radii of curvature are formed to be large at one, two, and three curves out of the four curves.

On the other hand, according to the semiconductor device 300 of the present embodiment, the number of the curves per conductor 42 is six, and the first ratio RT1 per conductor 42 can be selected from ⅙, 2/6, 3/6, 4/6, and ⅚. By adjusting the first ratio RT1 within a wider range of ⅙ or more and ⅚ or less, it is possible to suppress the concentration of the electric field while suppressing an increase in Vth.

It is also considered that, in some regions of the semiconductor device, all of the six curves may have a radius of curvature larger than the reference length LS. In contrast, it is also considered that all of the six curves may have a radius of curvature smaller than the reference length LS. Accordingly, the first ratio RT1 can also have a value within a range of less than ⅙ or more than ⅚. However, for each of the curves of the conductors 42, it is desirable that the curves include at least two types of radii of curvature, that is, the first radius of curvature R1 having a large curve and the second radius of curvature R2 having a small curve, in order to reduce the concentration of the electric field while suppressing an increase in Vth.

As the first ratio RT1 increases, a rapid increase in the current in the vicinity of VG=Vth can be suppressed, and the reliability of the semiconductor device can be improved. On the other hand, in a case where the first ratio RT1 is increased to a certain value or more, the value of Vth may be increased. Therefore, the value of the first ratio RT1 needs to be optimized in the semiconductor device, and an expanded range of possible values enables the improvement of the characteristics of the semiconductor device.

### Fourth Embodiment

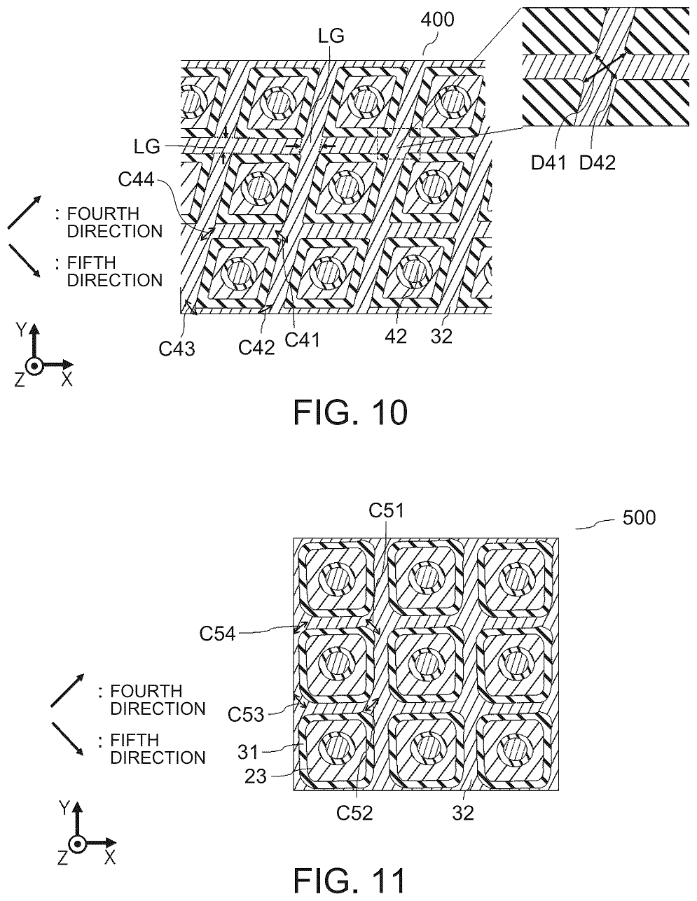

FIG. 10 is a diagram illustrating a semiconductor device 400 according to a fourth embodiment. Some redundant descriptions of the components common to the semiconductor device 100 according to the first embodiment will not be repeated.

In FIG. 10, the structure in which the gate electrodes 32 extend in the X direction and the Y direction are the same as those in FIG. 3, but the gate electrodes 32 extending in the X direction and the gate electrode 32 extending in the direction intersecting with the X direction intersect at an acute angle. That is, the gate electrodes 32 are provided in the parallelogram lattice shape in the XY plane. The width of the gate electrode 32 extending in the X direction and the width of the gate electrode extending in the direction intersecting the X direction have, for example, a common length LG.

A curve C41 is positioned in the positive directions of the X direction and the Y direction, and the respective curves are referred to in order clockwise from the curve C41 as curves C42, C43, and C44. The curve C41 has a smaller radius of curvature than those of the curve C42 and the curve C44. The curve C43 has a smaller radius of curvature than those of the curve C42 and the curve C44.

The length D41 is a distance between curves opposite to each other in the fourth direction. The length D42 is a distance between curves opposite to each other in the fifth direction. The length D41 is larger than the length D42.

According to the semiconductor device 400 of the present embodiment, it is possible to improve the reliability of the semiconductor device related to switching by the structure including the curves having a small radius of curvature and the curves having a large radius of curvature.

As an angle of the acute angle formed by the intersection of the gate electrodes 32 decreases, the radius of curvature of the curves C41 and C43 decreases, and the radius of curvature of the curves C42 and C44 increases. Therefore, a curve having a desired radius of curvature can be formed by adjusting the angle of intersection of the gate electrodes 32 in the lattice shape.

### Fifth Embodiment

FIG. 11 is a cross-sectional view of a semiconductor device 500 according to a fifth embodiment. Some redundant descriptions of the components common to the semiconductor device 100 according to the first embodiment will not be repeated.

In the semiconductor device 500 according to the present embodiment, a plurality of curves include a portion where the gate insulating film 31 is provided thick and a portion where the gate insulating film 31 is provided thin. For example, the gate insulating film 31 has four curves per conductor 42, and a curve C51 is positioned in the positive directions of the X direction and the Y direction. The respective curves are referred to in order clockwise from the curve C51 as curves C52, C53, and C54. The curve C51 has a thicker gate insulating film 31 than those of the curves C52, C53, and C54.

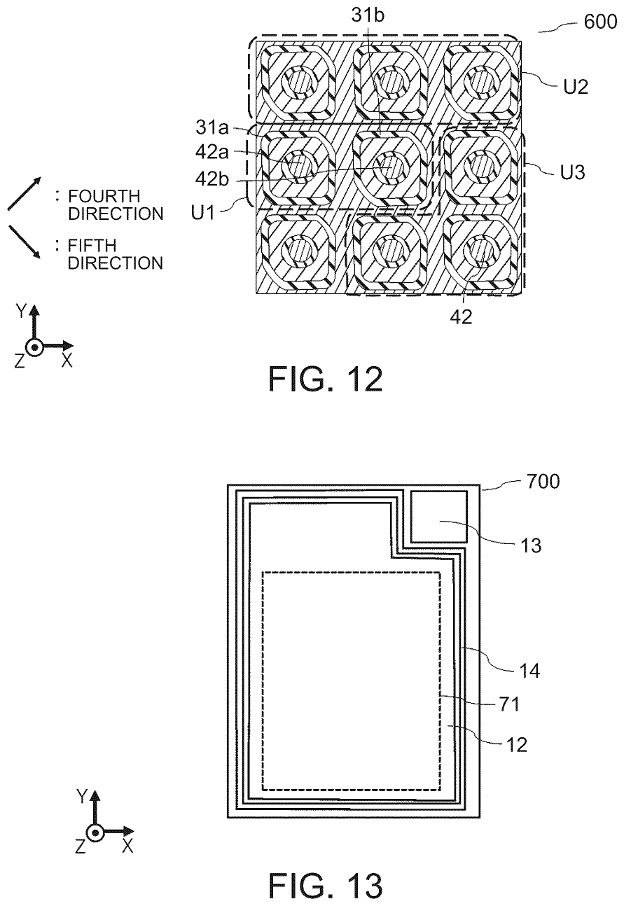

In the curve C51, the gate insulating film 31 is formed to be thick, and the gate insulating film 31 protrudes in the direction toward the gate electrode 32 as compared with the other curves C52, C53, and C54. Although FIG. 12 illustrates an example in which the gate insulating film 31 is formed to be thick at one curve out of the four curves, the gate insulating film 31 may be formed to be thick at two curves, or the gate insulating film 31 may be formed to be thick at three curves, for example.

In general, the thicker the gate insulating film 31, the smaller the intensity of the electric field induced in the second semiconductor region 22 by the voltage applied to the gate electrode 32. Therefore, a channel is less likely to be generated, and the threshold voltage Vth increases.

A structure in which the thickness of the gate insulating film 31 is changed for each curve can be formed, for example, by adding impurities to a part of the third semiconductor region 23 and changing the thickness of the oxide film by accelerated oxidation.

According to the semiconductor device 500 of the present embodiment, it is possible to improve the reliability of the semiconductor device related to switching by making the thickness of the gate insulating film 31 different for each curve. The semiconductor device 500 includes both a curve with the gate insulating film 31 formed to be thick and a curve with the gate insulating film 31 formed to be thin. The threshold voltage Vth is mainly determined by the thin curve of the gate insulating film 31. Therefore, the threshold voltage Vth can be maintained at a low level. On the other hand, as compared with the case where all the curves of the gate insulating film 31 are formed to be thin, the magnitude of the current at the time of switching can be controlled, and the reliability can be improved.

### Sixth Embodiment

FIG. 12 is a cross-sectional view of a semiconductor device 600 according to a sixth embodiment. Some redundant descriptions of the components common to the semiconductor device 100 according to the first embodiment will not be repeated.

The groups U1, U2, and U3 illustrated in FIG. 12 will be described. The groups U1, U2, and U3 are regions including one or more (when n is a natural number, n conductors) conductors 42. The gate insulating films 31 provided to surround a plurality of the conductors 42 included in a certain group (for example, U1) include those having different numbers of curves having a large radius of curvature. For example, in U1, a gate insulating film 31a surrounding a first conductor 42a has a large radius of curvature for three curves out of the four curves. On the other hand, a gate insulating film 31b surrounding a second conductor 42b has a large radius of curvature for two curves out of the four curves. That is, the curve shape of the gate insulating film 31 is different between the first conductor 42a and the second conductor 42b. Even in a group including three or more conductors 42, it is sufficient that the group has at least two types of curve shapes, and as illustrated in groups U2 and U3 of FIG. 12, the groups may include the gate insulating films 31 having the same shape.

The group U1 has two conductors 42 adjacent in the X direction. Note that the groups may include three or more conductors as illustrated by the group U2, or may include conductors 42 adjacent in the Y direction as illustrated by the group U3. Note that the groups may include conductors 42 that are not adjacent to each other. It is desirable to arrange the groups periodically in order to distribute the current density.

According to the semiconductor device 500 of the present embodiment, by more finely adjusting the first ratio RT1 in the groups, it is possible to suppress an increase in the threshold voltage Vth and the on-resistance and improve the reliability of the semiconductor device related to switching.

For example, since the group U1 includes two conductors 42, and a curve having a large radius of curvature can be selected from a total of eight curves, the first ratio RT1 per group U1 can be selected from ⅛, 2/8, . . . ⅞. Furthermore, by combining the groups having the first ratios RT1, the first ratio RT1 can be within a range of ⅛ or more and ⅞ or less.

In addition, since the group U2 includes three conductors 42 and has the four curves per conductor 42, the first ratio RT1 can be selected from 11 options: 1/12, 2/12, . . . 11/12. Furthermore, by combining a plurality of the groups U2, the first ratio RT1 can be within a range of 1/12 or more and 11/12 or less. Therefore, the range of possible values for optimizing the first ratio RT1 is further expanded.

Furthermore, in a case where the group generally has N conductors 42 and has six curves per conductor as illustrated in FIG. 9, the first ratio RT1 can be selected within a range of ⅙N<RT1<(6N−1)/6N. In a case where the conductor has four curves per conductor, the first ratio RT1 can be selected within a range of ¼N<RT1<(4N−1)/4N.

Therefore, by appropriately selecting the first ratio RT1 from a wide range, the current density at the time of switching can be suppressed while the on-resistance is maintained at a low-level, and the reliability can be improved.

### Seventh Embodiment

FIG. 13 is a schematic plan view illustrating a semiconductor device 700 according to a seventh embodiment. In the semiconductor device 700, a first region and a second region are defined in the XY plane, and the first region is formed to have a first ratio RT1 smaller than that of the second region.

First, an example of the first region will be described. The first region is, for example, a connection region 71 that is a region surrounded by a dotted line in FIG. 13. Here, the connection region 71 represents a region where a conductive member represented by, for example, a metal plate is provided on the second electrode 12. In the connection region 71, heat dissipation from a semiconductor element is promoted via the conductive member.

On the other hand, the second region is defined as, for example, a region around the first region. The second region is a region where heat dissipation by the conductive member such as the metal plate is inferior to the first region.

In the semiconductor device 700 according to the present embodiment, the first ratio RT1 varies in the X direction or the Y direction. As the first ratio RT1 is larger, the proportion of the curves having a large radius of curvature is larger, and the current is less likely to concentrate at the time of switching. In the first region, the first ratio RT1 is formed to be smaller than that in the second region.

Although not illustrated, the first region and the second region may be defined as follows. The first region is defined as a region farther from a gate pad 13 than the second region in the XY plane. In the first region farther from the gate pad 13, the first ratio RT1 is formed to be smaller than that in the second region closer to the gate pad 13.

In a case where a gate voltage VG is controlled via the gate pad 13, the delay of the gate voltage VG is small at a position closer to the gate pad 13, so that a channel is easily formed at an earlier timing. That is, the current density tends to increase in a region closer to the gate pad 13 at the time of turn-on.

According to the semiconductor device 700 of the present embodiment, the first ratio RT1 varies in the XY plane, and for example, by increasing the first ratio in a region having poor heat dissipation to suppress the current density, it is possible to improve the reliability of the semiconductor device related to switching. Alternatively, the reliability can be improved by increasing the first ratio RT1 in a region where the current density tends to increase at the time of switching.

The first region overlapping the connection region 71 in the Z direction dissipates heat generated by a current flowing the through semiconductor elements via the conductive member. Therefore, even in a case where a small first ratio RT1 is formed in the first region, and the current density at the time of switching is increased, by increasing the heat dissipation, it is possible to minimize destruction due to heat generation and to improve reliability.

In contrast, in the second region inferior in heat dissipation to the first region, by forming the first ratio RT1 larger than that of the first region, it is possible to suppress the current density at the time of switching, to suppress heat generation, and to improve reliability.

In addition, the first region and the second region can also be defined by the distance to the gate pad 13, and the first ratio RT1 is decreased as the distance from the gate pad 13 increases. The current does not concentrate in the region close to the gate pad 13; thereby, the current at the time of turn-on can be dispersed. It is possible to suppress local heat generation by dispersing the current. Therefore, the reliability of the semiconductor device related to switching can be improved.

According to the semiconductor device of at least one of the first to seventh embodiments described above, the curves having the first radius of curvature R1 and the second radius of curvature R2 smaller than the first radius of curvature R1 are provided, and the channel is formed first in a part of the curve of the gate insulating film 31 when the gate voltage is controlled to cause the turn-on operation. Therefore, it is possible to improve the reliability of the semiconductor device related to switching while suppressing an increase in the on-resistance by suppressing an increase in the threshold voltage Vth.

The embodiments have been described above with reference to specific examples. However, the embodiments are not limited to these specific examples. That is, those obtained by appropriately changing the design of these specific examples by those skilled in the art are also included in the scope of the embodiments as long as they have the features of the embodiments. Each element included in each specific example described above and the arrangement, material, condition, shape, size, and the like thereof are not limited to those exemplified, and can be appropriately changed.

In addition, each element included in each of the above-described embodiments can be combined as far as technically possible, and combinations thereof are also included in the scope of the embodiments as long as they include the features of the embodiments. In addition, within the scope of the idea of the embodiments, a person skilled in the art can conceive various modification examples and amended examples, and it is understood that the modification examples and amended examples also belong to the scope of the embodiment.

Although some embodiments of the present invention have been described, these embodiments have been presented as examples, and are not intended to limit the scope of the invention. These novel embodiments can be implemented in various other forms, and various omissions, substitutions, and changes can be made without departing from the gist of the invention. These embodiments and modifications thereof are included in the scope and gist of the invention, and are included in the invention described in the claims and the equivalent scope thereof.

What is claimed is:

1. A semiconductor device comprising:
a first electrode;
a substrate that includes
a first semiconductor region with a first conductivity type provided on the first electrode,
a second semiconductor region with a second conductivity type provided on the first semiconductor region, and
a third semiconductor region with the first conductivity type provided on the second semiconductor region;
a second electrode provided on the substrate;
a conductor provided between the first semiconductor region and the second electrode;
an insulator provided between the conductor and the substrate;
a gate electrode provided around the conductor and provided between the first semiconductor region and the second electrode; and
a gate insulating film provided between the gate electrode and the substrate, wherein
the gate insulating film has a plurality of curves in a first plane including a second direction intersecting with a first direction and a third direction intersecting with the first direction and the second direction, where the first direction is from the first electrode toward the first semiconductor region, and
the plurality of curves includes a curve having a first radius of curvature R1 and a curve having a second radius of curvature R2 smaller than the first radius of curvature R1.

2. The semiconductor device according to claim 1, wherein
the gate electrode is provided in a lattice shape in the first plane.

3. The semiconductor device according to claim 2, wherein
the gate electrode is provided in a rectangular lattice shape along the second direction and the third direction in the first plane.

4. The semiconductor device according to claim 1, wherein
a first length in a fourth direction, which is located between a positive direction of the second direction and a positive direction of the third direction, between curves opposing each other via the gate electrode, is larger than a second length in a fifth direction, which is located between the positive direction of the second direction and a negative direction of the third direction in the first plane, between curves opposing each other via the gate electrode.

5. The semiconductor device according to claim 1, wherein
a third length that is a maximum value of a distance in the second direction between curves opposing each other via the gate electrode, is larger than a fourth length that is a maximum value of a distance in the third direction between curves opposing each other via the gate electrode.

6. The semiconductor device according to claim 2, wherein
an intersection of the gate electrode provided in the lattice shape includes a T-shaped intersection or a Y-shaped intersection in the first plane.

7. The semiconductor device according to claim 1, wherein
the curve having the first radius of curvature R1 among the plurality of curves is positioned in a common direction with respect to each of a plurality of the conductors.

8. The semiconductor device according to claim 1, wherein
the gate insulating film has four curves per conductor, and one or more and three or less curves out of the four curves have a radius of curvature longer than a reference length LS, defined as LS=(R1+R2)/2.

9. The semiconductor device according to claim 1, wherein
a plurality of groups, each having n conductors, is provided, where n is a natural number, and
a first ratio RT1 that is a ratio of curves with a radius of curvature larger than a reference length LS defined as (R1+R2)/2, included in the plurality of groups, is 1/(6n) or more and (6n-1)/(6n) or less.

10. The semiconductor device according to claim 9, wherein
the first ratio in a first region defined in the first plane is smaller than the first ratio in a second region not including the first region.

11. The semiconductor device according to claim 10, wherein
the first region overlaps a region where a conductive member is provided on the second electrode in the first direction.

12. The semiconductor device according to claim 10, wherein
a gate pad electrically connected to the gate electrode is further provided on an upper surface of the substrate, and
the first region includes a region farther from the gate pad than the second region in the first plane.

13. A semiconductor device comprising:
a first electrode;
a substrate that includes a first semiconductor region with a first conductivity type provided on the first electrode,
a second semiconductor region with a second conductivity type provided on the first semiconductor region, and
a third semiconductor region with the first conductivity type selectively provided on the second semiconductor region;
a second electrode provided on the substrate;
a conductor provided between the first semiconductor region and the second electrode;
an insulator provided between the conductor and the substrate;
a gate electrode provided around the conductor and provided between the first semiconductor region and the second electrode; and
a gate insulating film provided between the gate electrode and the substrate, wherein
the gate insulating film has a plurality of curves in a first plane including a second direction intersecting with a first direction and a third direction intersecting with the first direction and the second direction, where the first direction is from the first electrode toward the first semiconductor region, and
the plurality of curves includes a portion where the gate insulating film is provided with a first thickness, and a portion where the gate insulating film is provided with a second thickness smaller than the first thickness.

14. The semiconductor device according to claim 13, wherein
the gate electrode is provided in a lattice shape in the first plane.

15. The semiconductor device according to claim 14, wherein
the gate electrode is provided in a rectangular lattice shape along the second direction and the third direction in the first plane.

16. The semiconductor device according to claim 13, wherein
a first length in a fourth direction, which is located between a positive direction of the second direction and a positive direction of the third direction, between curves opposing each other via the gate electrode, is larger than a second length in a fifth direction, which is located between the positive direction of the second direction and a negative direction of the third direction in the first plane, between curves opposing each other via the gate electrode.

17. The semiconductor device according to claim 13, wherein
a third length that is a maximum value of a distance in the second direction between curves opposing each other via the gate electrode, is larger than a fourth length that is a maximum value of a distance in the third direction between curves opposing each other via the gate electrode.
